(19) United States
(12) Patent Application Publication
(10) Pub. No.: US 2015/0173168 A1
(43) Pub. Date: Jun. 18, 2015

(54) DC/DC POWER MODULE AND DC/DC POWER SYSTEM HAVING THE SAME

(71) Applicant: Delta Electronics (Shanghai) Co., Ltd., Shanghai (CN)

(72) Inventor: Yuyang JIANG, Shanghai (CN)

(21) Appl. No.: 14/553,396

(22) Filed: Nov. 25, 2014

(30) Foreign Application Priority Data
Dec. 13, 2013 (CN) 201310684973.7

(51) Int. Cl. H05K 1/02

(52) U.S. Cl. CPC H05K 1/0203; H05K 2201/066

(57) ABSTRACT

A DC/DC power system comprises a DC/DC power module, a system board and a heating dissipation assembly. The DC/DC power module comprises a printed circuit board and at least one first heat sink. The printed circuit board is provided with at least one heating component and at least one connecting terminal for electrical connection on a first surface of said printed circuit board. The first heat sink covers the heating component on the first surface of the printed circuit board but exposes the connecting terminal. The system board is provided with an opening hole at a position corresponding to the DC/DC power module. The heating dissipation assembly is suitable for contacting with the DC/DC power module via the opening hole and dissipating heat from the DC/DC power module.

### CROSS-REFERENCE TO RELATED APPLICATIONS

This non-provisional application claims priority on Patent Application No. 201310684973.7 filed in P. R. China on Dec. 13, 2013, the entire contents of which are hereby incorporated by reference.

### BACKGROUND

1. Technical Field

The present disclosure relates to the field of DC/DC power supply, and particularly to a DC/DC power module and a DC/DC power system.

2. Description of Related Art

The DC/DC power modules have been widely used in the field of communication such as switching devices, access devices, mobile communication, microwave communication, optical transmission, routers, and in the fields of automotive electronics, aerospace and so on. In the field of communication, a communication system is generally supplied with −48V or +24V. The system may include one or more DC/DC power modules for converting the supplied DC voltage into the DC operating voltage required by the circuit boards. As the increase of the demand for the power density and conversion efficiency of the DC/DC power module, there is an urgent need to provide a DC/DC power module, which is compact, efficient and reliable.

As shown in FIGS. 1A and 1B, a common DC/DC power module 10 is mainly composed of a printed circuit board (PCB) 11, at least one heating component 12, and the connecting terminals 13 for electrical connection. This DC/DC module power is of the type of open frame, which does not have any heat sink and is therefore unfavorable for heat dissipating.

As shown in FIGS. 2A and 2B, another DC/DC power module 20 in the conventional solution is mainly composed of a printed circuit board (PCB) 21, at least one heating component 22, connecting terminals 23 for electrical connection, and at least one heat sink 24. The heat sink 24 is disposed on the PCB 21. The heat sink 24 and the connecting terminals 23 are respectively arranged on opposite surfaces of the PCB 21. As shown in FIGS. 2C and 2D, when the DC/DC power module 20 of such construction is put into application, the connecting terminals 23 are soldered to a system board 21′, while the heat sink 24 is connected with a customer heat spreader 22′. That is, the customer heat spreader 22′ is installed at a front face of the DC/DC power module 20. The term “front face” herein refers to the face that is opposite to the connecting terminals 23. In the DC/DC power module of such a construction, the heat sink 24 and the connecting terminals 23 are respectively arranged at different surfaces of the PCB 21. During operation, the connecting terminals 23 are soldered to the system board 21′, while the heat sink 24 is directly connected with the customer heat spreader 22′. Thus, a relatively large space is required for installation, which results in insufficiency of space and difficulty of installing the DC/DC power module.

### SUMMARY

An objective of the present disclosure is to provide a DC/DC power module, which can reduce the required space at the customer side and/or be adaptable for a system in which the customer heating dissipation assembly is installed below the DC/DC power module.

According to an aspect of the disclosure, a DC/DC power module comprises a printed circuit board provided with at least one heating component and at least one connecting terminal for electrical connection on a first surface of said printed circuit board; and at least one first heat sink covering the heating component and exposing the connecting terminal.

According to another aspect of the disclosure, a DC/DC power system comprises a DC/DC power module, a system board and a heating dissipation assembly. Said DC/DC power module comprises a printed circuit board provided with at least one heating component and at least one connecting terminal for electrical connection on a first surface of said printed circuit board, and at least one first heat sink covering the heating component and exposing the connecting terminal. Said system board is provided with an opening hole at a position corresponding to the DC/DC power module. Said heating dissipation assembly is suitable for contacting with the DC/DC power module via the opening hole and dissipating heat from the DC/DC power module.

According to the disclosure, the heating component and the connecting terminal(s) for electrical connection of the DC/DC power module are disposed on the same surfaces of the PCB, while the first heat sink covers the heating component but exposes the connecting terminal(s), so that the overall thickness of the DC/DC power module is reduced. When the DC/DC power module of the disclosure is applied at the customer side to constitute the power system, an opening hole is arranged in the system board, through which the heating dissipation assembly penetrates to contact with the DC/DC power module so as to perform heat dissipating on the DC/DC power module. The distance between the heat spreader and the system board can be adjusted by changing the height of a heat conducting block. In this way, the DC/DC power system of the disclosure is compact in structure, small in space for installation, and can be simply and flexibly installed.

The present disclosure will be described in detail hereinafter by referring to the accompanying drawings and the specific embodiments, which should by no means be construed as limitations to the present disclosure.

### BRIEF DESCRIPTION OF THE DRAWINGS

FIG. 1A is a perspective view of a conventional DC/DC power module;

FIG. 1B is a perspective view of the DC/DC power module of FIG. 1A viewing in another direction;

FIG. 2A is a perspective view of another conventional DC/DC power module;

FIG. 2B is a perspective view of the DC/DC power module of FIG. 2A viewing in another direction;

FIG. 2C is a exploded perspective view showing the DC/DC power module of FIG. 2A, which is applied and installed at the customer side;

FIG. 2D is an elevational side view of the DC/DC power module of FIG. 2A, which is applied and installed at the customer side;

FIG. 3A is a perspective view of a DC/DC power module of the illustrative embodiment of the disclosure;

FIG. 3B is an exploded perspective view of the DC/DC power module as shown in FIG. 3A;

FIG. 3C is an exploded perspective view of a DC/DC power system of the illustrative embodiment of the disclosure;

FIG. 3D is a partial cross-sectional side view of the DC/DC power system as shown in FIG. 3C; and

FIG. 3E is a perspective view of a customer system board in FIG. 3C.

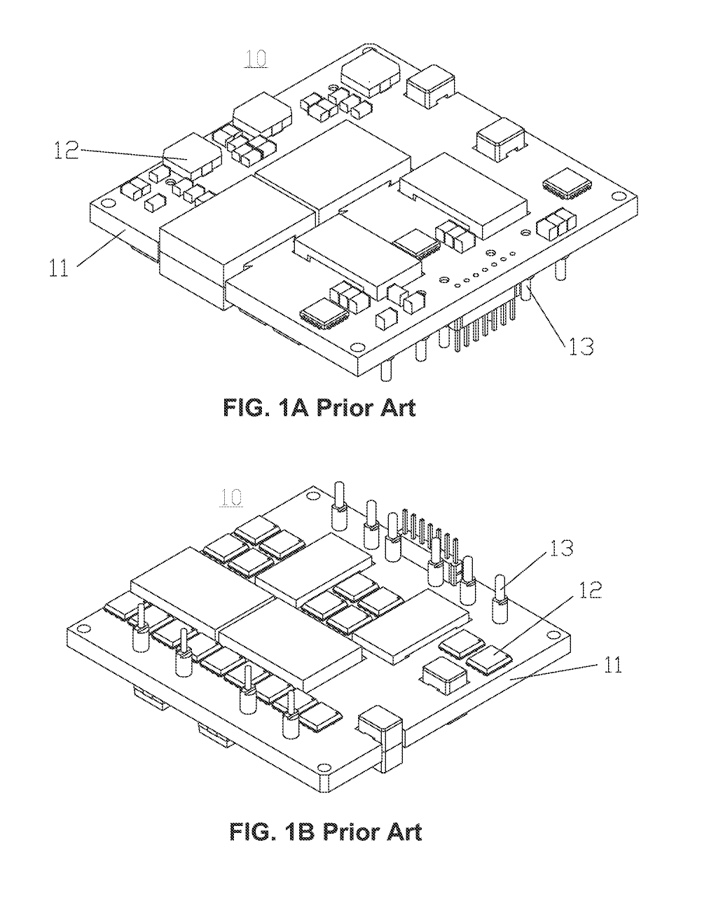

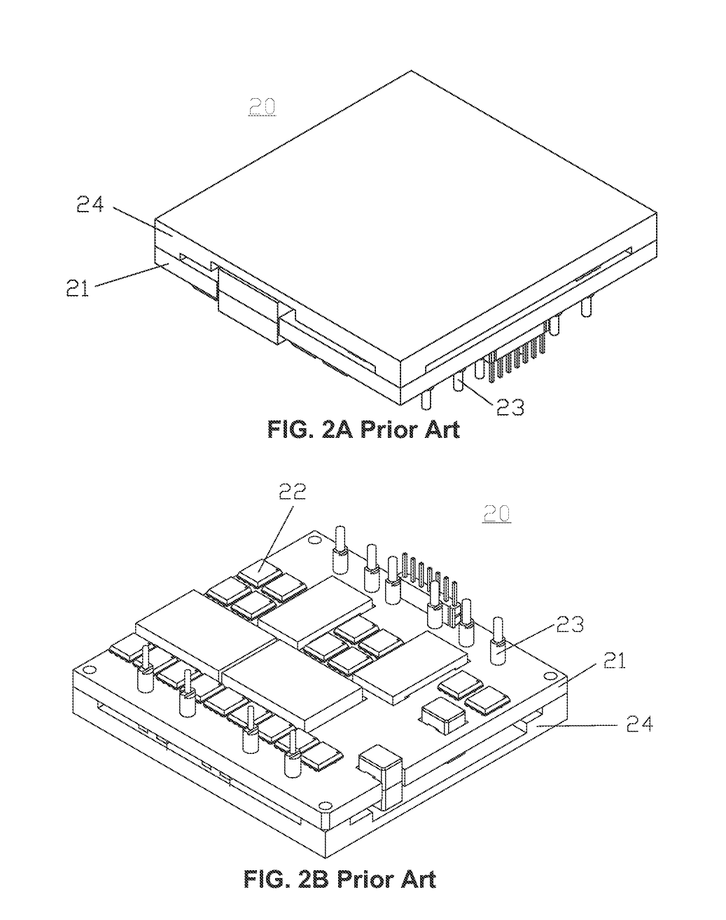

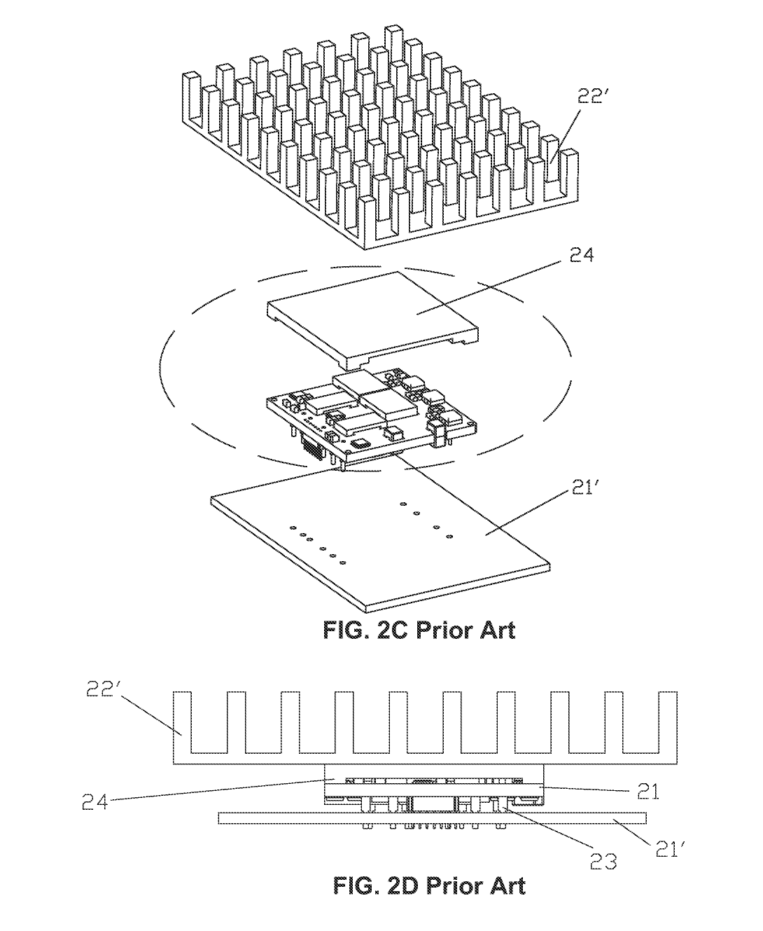

### DETAILED DESCRIPTION

The disclosure will now be described in details through following illustrative embodiments. However, it should be understood that an element, a structure or a feature in an embodiment can be beneficially incorporated into other embodiments without further recitation.

Some references, if any, which may include patents, patent applications and various publications, may be cited and discussed in the description of this disclosure. The citation and/or discussion of such references, if any, is provided merely to clarify the description of the present disclosure. All references listed, cited and/or discussed in this specification are incorporated herein by reference in their entireties and to the same extent as if each reference was individually incorporated by reference.

It should also be understood that “comprises/comprising” when used in the specification is taken to specify the presence of stated features, integers, steps or components but does not preclude the presence or addition of one or more other features, integers, steps or components or groups thereof.

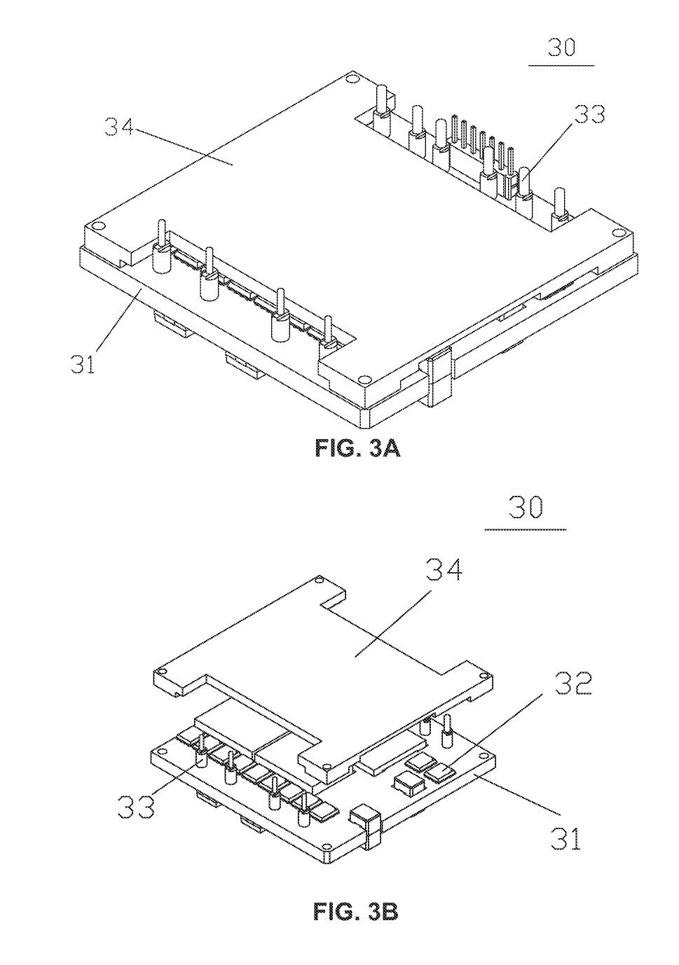

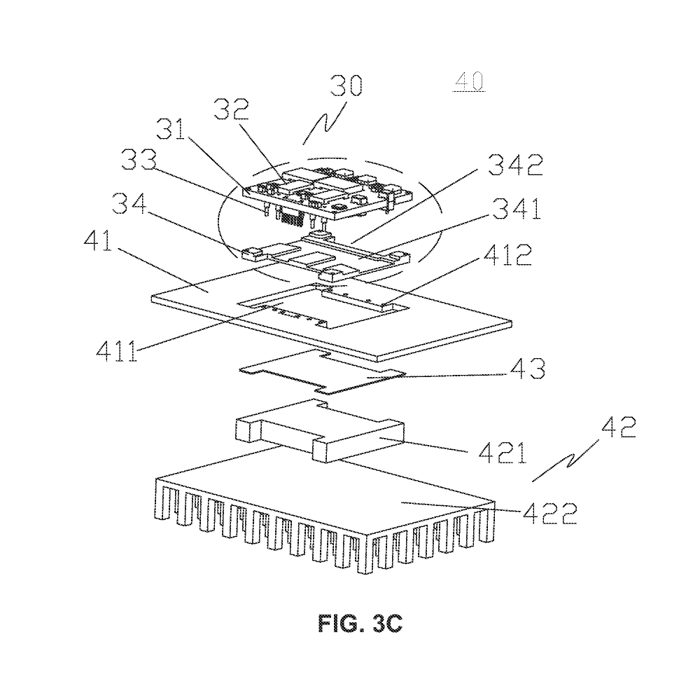

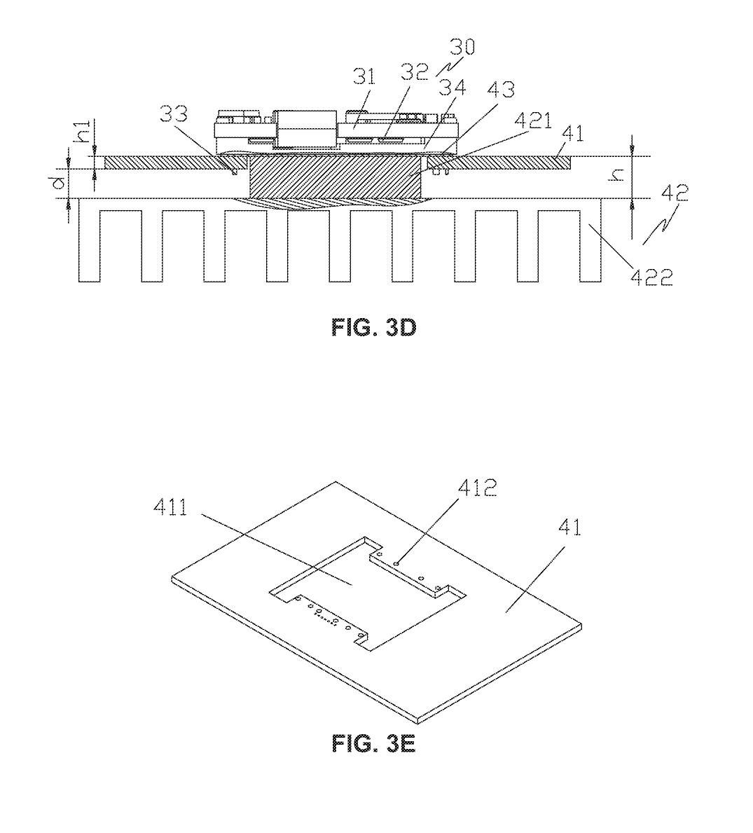

Reference is made to FIGS. 3A and 3B. As shown in the drawings, a DC/DC power module 30 of the disclosure comprises a printed circuit board (PCB) 31 and a first heat sink 34. On one surface (a first surface) of the PCB 31, one or more heating components 32 and one or more connecting terminals 33 for electrical connection are arranged. The number of the heating component(s), as well as the number of the connecting terminal(s) can be one, or two or more, depending on the needs in practice. Generally, the heating component in the DC/DC power module 30 may be such as a power switch, a transformer or the like.

As can be seen from FIGS. 3A and 3B, the first heat sink 34 and the connecting terminals 33 are arranged on the same surface of the PCB 31, with the first heat sink 34 covering the heating components 32 but exposing the connecting terminals 33. Usually, the first heat sink 34 has a height smaller than that of the connecting terminals 33. As a result, when the whole DC/DC power module 30 is installed on an application board, the thickness of the first heat sink 34 and the thickness of the heating components 32 can be accommodated within the space formed by the connecting terminals 33 and between the DC/DC power module 30 and the application board. Thus, as compared with the conventional power module, the thickness of the DC/DC power module 30, as well as the overall thickness of the combination of the DC/DC power module 30 and the application board on which the module 30 is installed, can be reduced.

In this embodiment, the connecting terminals 33 are arranged respectively along two parallel edges of the PCB 31. The height of the respective heating components 32 on the PCB 31 may be different from one another. In order to fit all of the heating components 32 on the first surface of the PCB 31, a face of the first heat sink 34 that faces the first surface of the PCB 31 is configured to be of uneven and complementary to the height of the heating components 32 on the first surface of the PCB 31 in such a way that the first heat sink 34 can completely fit all the heating components 32 on the first surface of the PCB 31. Corresponding to the arrangement of the connecting terminals 33, the first heat sink 34 is provided with two openings 342 for exposing the connecting terminals 34 arranged along the two edges of the PCB 31. The first heat sink 34 is thus generally H-shaped.

According to another embodiment of the disclosure, the DC/DC power module 30 of the disclosure can further comprises a second heat sink covering the other surface (a second surface) of the PCB 31. On the second surface of the PCB 31, one or more heating components 32 can be provided, the number of which can be one, or two or more, depending on the needs in practice. Accordingly, the face of the second heat sink that faces the second surface of the PCB 31 can be configured to be of uneven and complementary to the height of the heating components 32 on the second surface of the PCB 31 in such a way that the second heat sink can completely fit all the heating components 32 on the second surface of the PCB 31. Alternatively, there can be no heating component on the second surface of the PCB 31. In this case, the second heat sink can be configured to completely fit the second surface of the PCB 31. Due to the arrangement of the second heat sink, heat can be dissipated from both surfaces of the DC/DC power module 30. The efficiency of heat dissipating is further improved.

Referring to FIGS. 3C and 3E, a DC/DC power system 40 according to the disclosure comprises a DC/DC power module 30, a system board 41 and a heating dissipation assembly 42. An opening hole 411 is provided in the system board 41 at a position corresponding to the DC/DC power module 30. The opening hole 411 is configured and shaped to match the shape of the first heat sink 34 of the DC/DC power module 30, so as to facilitate heat dissipating from the DC/DC power module 30 to the maximum extent. That is, when the first heat sink 34 is generally H-shaped, the opening hole 411 is accordingly generally H-shaped. The system board 41 is also provided with through holes 412 at a position corresponding to the connecting terminals 33 of the DC/DC power module 30, through which the connecting terminals 33 can pass. As shown in FIG. 3D, the heating dissipation assembly 42 and the power module 30 are respectively arranged at two opposite surfaces of the system board 41.

The heating dissipation assembly 42 contacts with the DC/DC power module 30 via the opening hole 411, to dissipate the heat from the DC/DC power module 30. The heating dissipation assembly 42 comprises a heat conducting block 421 and a heat spreader 422. In order to contact with the first heat sink 34, the heat conducting block 421 is protruded at the position corresponding to the opening hole 411, so as to contact with the first heat sink 34 of the DC/DC power module 30 through the opening hole 411. The opposite face of the heat conducting block 421 contacts with the heat spreader 422, so that heat from the DC/DC power module 30 can be dissipated to the heat spreader 422 via the heat conducting block 421 and then dissipated from the heat spreader 422. Furthermore, in another embodiment, when a single heat spreader 422 is shared by all modules that require heat dissipating on the system board 41, the difference in height between the DC/DC power module 30 and other modules requiring heat dissipating on the system board 41 can be compensated by the thickness of the heat conducting block 421. In an embodiment, the thickness h of the heat conducting block 421 can be determined by the equation of

h=h1+d

wherein, h1 is a thickness of the system board 41, d is a distance between the heat spreader 422 of the heating dissipation assembly 42 and the system board 41.

The heating dissipation assembly 42 further comprises a heat conducting gasket 43. The heat conducting gasket 43 is disposed between the heat conducting block 421 and the first heat sink 34, and has a shape which corresponds to that of the first heat sink 34. The heat conducting gasket 43 can be made from resin or silicone, and is designed and configured to be closely fit between the heat conducting block 421 and the first heat sink 34, so as to avoid any gap between the heat conducting block 421 and the first heat sink 34 due to the uneven contacting surfaces of them, and thus improve the efficiency of heat dissipating.

It can be seen from the above description on construction that, due to the arrangement of the opening hole and through holes, the DC/DC power module and the heating dissipation assembly can be arranged at two opposite surfaces of the system board, while the heat can be well dissipated from the DC/DC power module. As compared with the conventional DC/DC power module, the DC/DC power module of the disclosure occupies a relatively small space at one surface of the system board, which facilitates a low profile of the DC/DC power system.

Although several preferred embodiments of the present disclosure have been described, the present disclosure may be used with other configurations. It will be appreciated by those skilled in the art that, the present disclosure could have many other embodiments, and changes and modifications may be made thereto without departing from the disclosure in its broader aspects and as set forth in the following claims and equivalents thereof.

What is claimed is:

1. A DC/DC power module, comprising:
a printed circuit board, provided with at least one heating component and at least one connecting terminal for electrical connection on a first surface of said printed circuit board; and
at least one first heat sink, covering the heating component and exposing the connecting terminal.

2. The DC/DC power module of claim 1, wherein the printed circuit board is provided with a plurality of the connecting terminals on the first surface, which are arranged respectively along two edges of the printed circuit board.

3. The DC/DC power module of claim 2, wherein the first heat sink is generally H-shaped.

4. The DC/DC power module of claim 1, further comprising at least one second heat sink, which covers a second surface of the printed circuit board, the second surface being opposite to the first surface of the printed circuit board.

5. A DC/DC power system, comprising:
a DC/DC power module, which comprises:
a printed circuit board, provided with at least one heating component and at least one connecting terminal for electrical connection on a first surface of said printed circuit board; and
at least one first heat sink, covering the heating component and exposing the connecting terminal;
a system board, provided with an opening hole at a position corresponding to the DC/DC power module; and
a heating dissipation assembly for contacting with the DC/DC power module via the opening hole and dissipating heat from the DC/DC power module.

6. The DC/DC power system of claim 5, wherein the heating dissipation assembly comprises a heat conducting block and a heat spreader, wherein the heat conducting block contacts with both the heat spreader and the DC/DC power module via the opening hole.

7. The DC/DC power system of claim 6, further comprising a heat conducting pad, which is arranged between the heat conducting block and the first heat sink of the DC/DC power module.

8. The DC/DC power system of claim 7, wherein the heat conducting pad has a shape corresponding to that of the first heat sink.

9. The DC/DC power system of claim 5, wherein the printed circuit board is provided with a plurality of the connecting terminals on the first surface, which are arranged respectively along two edges of the printed circuit board.

10. The DC/DC power system of claim 5, wherein the first heat sink is generally H-shaped.

11. The DC/DC power system of claim 5, wherein the DC/DC power module further comprises at least one second heat sink for covering a second surface of the printed circuit board, the second surface being opposite to the first surface of the printed circuit board.

12. The DC/DC power system of claim 6, wherein the heat conducting block has a thickness determined by the equation of
h=h1+d,
wherein h is the thickness of the heat conducting block,
h1 is a thickness of the system board, and
d is a distance between the heat spreader of the heating dissipation assembly and the system board.
